(19) United States
(12) Patent Application Publication
(10) Pub. No.: US 2009/0283865 A1
(43) Pub. Date: Nov. 19, 2009

(54) ELECTROCHEMICAL METHOD TO MAKE HIGH QUALITY DOPED CRYSTALLINE COMPOUND SEMICONDUCTORS

(75) Inventors: Xiaoyan Shao, Yorktown Heights, NY (US); Ronald Goldblatt, Yorktown Heights, NY (US); Ghavam G. Shahidi, Elmsford, NY (US)

Correspondence Address: Connolly Bove Lodge & Hutz LLP, Suite 1100, 1875 Eye Street, NW, Washington, DC, 20006, US

(73) Assignee: International Business Machines Corporation, Armonk, NY (US)

(21) Appl. No.: 12/122,257

(22) Filed: May 16, 2008

(51) Int. Cl. H01L 29/00; H01L 21/20

(52) U.S. Cl. 257/607; 438/509; 257/E21.324

(57) ABSTRACT

A process for fabricating doped crystalline semiconductors is provided using layer by layer deposition of semiconductors and the corresponding dopants.

### TECHNICAL FIELD

The present disclosure relates to a process for fabricating doped crystalline semiconductors. In particular, the present disclosure relates to a process that uses a separate solution to introduce dopants intermittently during the electrodeposition of semiconductors. The present disclosure makes it possible to obtain high quality doped crystalline semiconductors.

### BACKGROUND

High quality crystalline compound semiconductors are traditionally deposited by high vacuum processes with gas precursors, such as by molecular beam epitaxy or chemical vapor deposition. Dopant is subsequently introduced into the semiconductors by ion implantation to form electron-rich (n-type) or electron-deficient (p-type) regions in transistors. During ion implantation, dopant ions are accelerated to tens or hundreds of kiloelectron volts before reaching the semiconductor surface. Both gas phase semiconductor deposition process and ion implantation are high vacuum, high cost processes.

With the intensified needs for sustainable energy around the world, photovoltaic solar cells that are based on semiconductor materials has become a promising path. Both single crystalline and polycrystalline semiconductors are applicable in solar cell structures. Therefore there are increasing interests and needs for low cost doped semiconductors. Low cost is critical for the solar cell production in order to be competitive with conventional fossil-based energy resources.

Electrochemical atomic layer deposition (EC-ALD) is a technique for electrodepositing nanofilms, and has been used most extensively to form compound semiconductors as mentioned in U.S. Pat. No. 5,320,736, “Method to electrochemically deposit compound semiconductors”, disclosure of which is incorporated herein by reference. U.S. Pat. No. 5,320,736 relates to a method for depositing epitaxial single crystalline compound semiconductors on top of crystalline metallic substrates. EC-ALD is the electrochemical analog of ALE and ALD, all methods based on the use of surface limited reactions to form deposits with atomic layer control. The advantages of these methodologies are that they can be used to control deposition at the atomic level. The method breaks the deposition process into a sequence of individually controllable steps, thus greatly improving the ability to optimize a process.

Crystalline films can be electrodeposited by using electrochemical atomic layer deposition (EC-ALD). However, electrodeposition has never been used to co-deposit dopants, such as P, B, Al, Sb, Zn, Cd, C, Si, Ge and As during the deposition of semiconductors, such as Si, Ge, III-V, and II-VI compounds. The main reason is because it is difficult when employing conventional electrodeposition techniques to reliably control the dopant concentration at the levels that are used in most integrated circuits.

### SUMMARY OF DISCLOSURE

This disclosure provides for a low power and low cost method to electrodeposit semiconductors and incorporate dopant into the semiconductors during the electrodeposition. It has been found according to the present disclosure that dopants can be co-deposited by absorption or electrodeposition and the dopant concentration can be reliably controlled.

In particular, the present disclosure relates to a process for fabricating doped crystalline semiconductors. One aspect of the present disclosure relates to a process which comprises sequentially electrodepositing by atomic layer electrodeposition at least one atomic monolayer or submonolayer of a first element of a first solution and optionally at least one atomic monolayer or submonolayer of a second element of a second solution on a substrate; and repeating the sequential electrodepositing by atomic layer electrodeposition until at least one film of a semiconductor material is formed on the substrate to provide a semiconductor of a desired thickness. Next, a dopant chemical is introduced by absorption or electrodeposition after a desired number of sequences of making a semiconductor film.

The deposition by atomic layer electrodeposition is repeated until a desired thickness of semiconductor film and introduction of dopant intermittently until the desired final thickness is achieved. The deposited film is then annealed to permit diffusion of the dopant atoms throughout the film to obtain a uniform dopant concentration.

Another aspect of the present disclosure relates to a process which comprises electrodepositing by bulk electrodeposition a desired thickness of a first semiconducting element, compound, or alloy of a first solution on the substrate. Next, a dopant chemical is introduced by using the flow deposition system after a desired thickness of making a semiconductor film.

The deposition by electrodeposition is repeated until a desired thickness of semiconductor film and introduction of dopant intermittently until the desired final thickness is achieved. The deposited film is then annealed to permit diffusion of the dopant atoms throughout the film to obtain a uniform dopant concentration.

The present disclosure is also concerned with a doped crystalline semiconductor obtained by the above disclosed processes.

Still other objects and advantages of the present disclosure will become readily apparent by those skilled in the art from the following detailed description, wherein it is shown and described preferred embodiments, simply by way of illustration of the best mode contemplated. As will be realized the disclosure is capable of other and different embodiments, and its several details are capable of modifications in various obvious respects, without departing from the disclosure. Accordingly, the description is to be regarded as illustrative in nature and not as restrictive.

### BRIEF DESCRIPTION OF THE DRAWINGS

FIG. 1 illustrates a flow deposition system used for the formation of doped semiconductor films according to the present disclosure.

FIGS. 2A-2D are schematic diagrams illustrating depositing a doped compound semiconductor by EC-ALD method or under-potential deposition according to the present disclosure.

FIGS. 3A and 3B are schematic diagrams illustrating incorporating dopants by using the flow deposition system for bulk deposition of a semiconductor film with controlled introduction of dopants intermittently according to the present disclosure.

FIG. 4 represents a XPS scan of deposited InAs (curve 1) and standard sample (curve 2).

FIG. 5 is a graph that shows the SIMS depth profiling of a Si sample after 60 second deposition of NiP at 10 mA/cm² current density in a NiP deposition solution.

### DESCRIPTION OF BEST AND VARIOUS MODES FOR CARRYING OUT DISCLOSURE

In order to facilitate an understanding of the present disclosure, reference will be made to the figures where like numerals in different views refer to the same component.

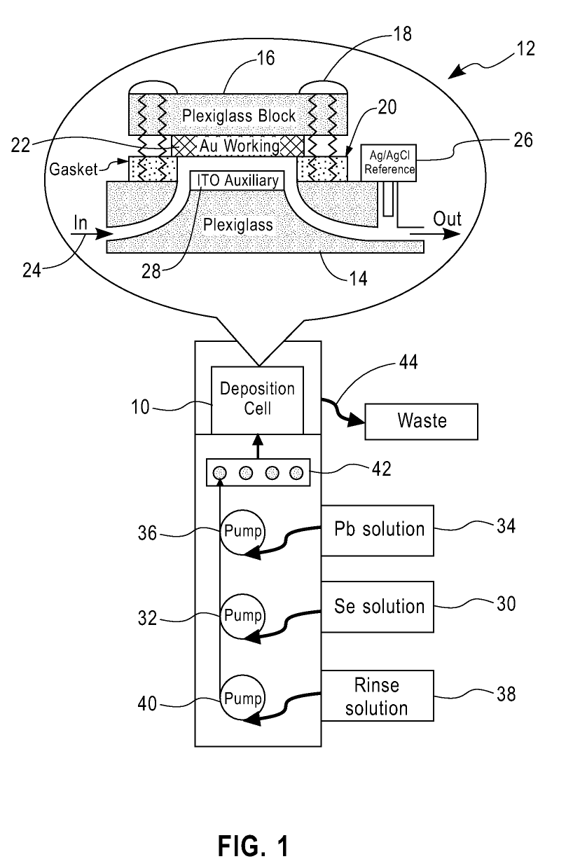

More particularly, FIG. 1 illustrates a flow deposition system used for the formation of doped semiconductor films according to the present disclosure wherein numeral 10 generally refers to the deposition cell and 12 provides details of the deposition cell. Numerals 14 and 16 refer to the bottom and top housing, respectively of the deposition cell, which can be fabricated from a material such as plexiglass. The top 16 and bottom 14 are held together by fasteners 18 and gaskets 20. Numeral 22 illustrates the substrate upon which the doped semiconductor is to be formed. In this particular case, the substrate 22 is a gold substrate, with an understanding that this disclosure is not limited to gold. Conduit 24 provides for introducing the electrodeposition solutions and for removing the solutions after use. Numeral 26 refers to the reference electrode such as a silver/silver chloride reference electrode. Numeral 28 refers to an ITO auxiliary (Indium Tin Oxide, a transparent conductive oxide) auxiliary counter electrode. Numeral 30 represents source for the semiconductor material that can be introduced into the deposition cell 10 by pump 32. Numeral 34 represents source for the dopant material that can be introduced into the deposition cell 10 by pump 36. Numeral 38 represents source for a rinse solution that can be introduced into the deposition cell 10 by pump 40. Valves 42 control which solution is being introduced into deposition cell 10 at any particular time.

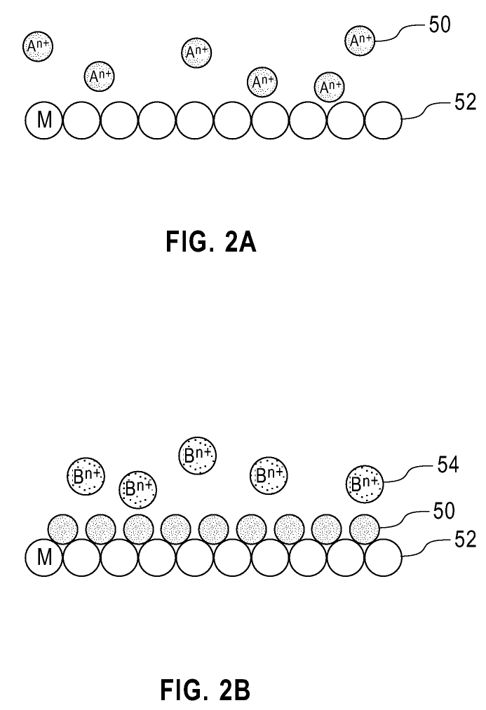

FIG. 2A illustrates the initial step of the process of this disclosure to electrodeposit a first element 50 represent by A^{m+} of a first solution onto a conductive surface 52 represented by M. Examples of suitable substrates are gold, steel, glass with conductive surface coating, ceramic with conductive surface coating, and plastic with conductive surface coating.

A represents a component of or the material of the semiconductor and n+ being its valence. Examples of materials for A are Si, Ge, Group III and Group II elements.

When the semiconductor is a compound material such as a III-V or II-VI semiconductor or SiGe, the second component 54 is electrodeposited. In particular, a second element 54 represent by Bⁿ⁺ of a second solution onto the layer of the first element 50. B being a component of the semiconductor and m+ being its valence. Examples of materials for B are Group V and Group VI elements, and Si and Ge.

The electodeposition for 50 and 54 in this exemplary method provides monolayers or submonolayers by EC-ALD method or under-potential method. The term “submonolayer” refers to a layer that does not extend over all of the underlying substrate.

The above steps are repeated (see FIG. 2C) to provide a relatively thin nano-film of a compound AmBn. Typical thicknesses of the film are about 10 nanometers to about 1000 nanometers and more typically about 20 nanometers to about 100 nanometers.

After the desired thickness of the semiconductor film is formed; a dopant chemical 56 represented as D^{x+} is deposited by EC-ALD method or under-potential deposition. See FIG. 2C. Examples of dopant materials include P, B Al, Sb, Zn, Cd, C, Si, Ge and As. The dopant concentration can be regulated with the charge passed during this deposition, and it can also be controlled by changing the relative cycle number of the steps depositing the semiconductor materials versus the step depositing the dopant.

Typical concentrations of the dopant is about 0.1% to about 10% and more typically about 0.5% to about 5%.

The above steps are followed by repeating the deposition of a certain thickness of semiconductor film and introduction of dopant intermittently until the final desired thickness is achieved. Typical final layer thicknesses are about 10 nanometers to about 10 microns and more typically about 100 nanometers to about 1 micron.

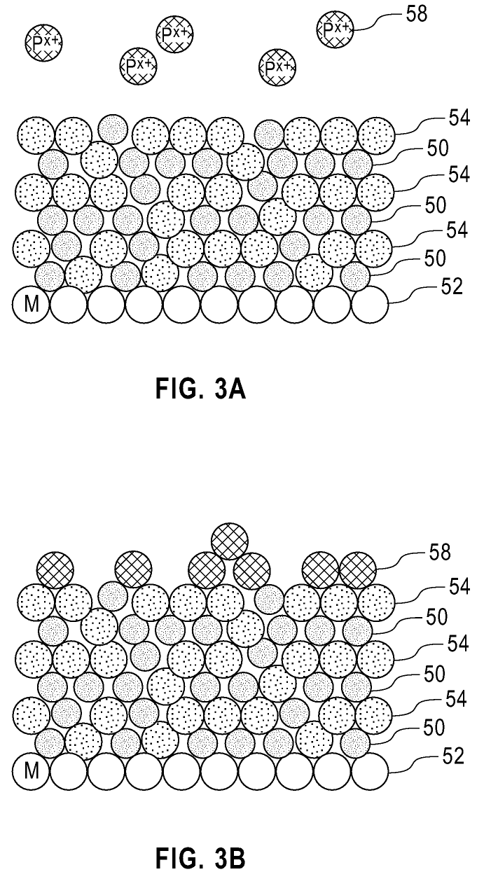

Next the deposited film is annealed to improve the crystallinity of the semiconductor film and cause the dopant atoms to diffuse throughout the film to obtain uniform dopant concentration. See FIG. 4D. The annealing is typically carried out at temperatures of about 400° C. to about 1200° C. and more typically about 700° C. to about 1000° C. for about 5 seconds to about 120 minutes and more typically about 30 seconds to about 30 minutes.

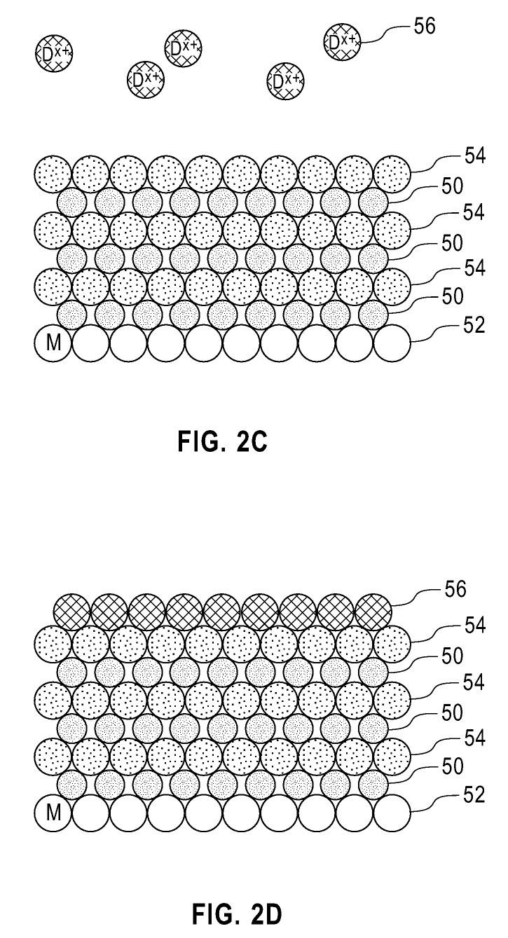

FIG. 3 illustrates an alternative method according to the present disclosure to incorporate dopants (D) in a reliable way into semiconductors during bulk electrochemical deposition. FIG. 3A illustrates electrodepositing a very thin layer of semiconductor materials 50, 54, which can be Si, Ge, SiGe, Group II-V, or Group II-VI compounds, onto a conductive surface 50 using a conventional bulk electrodeposition method.

FIG. 3B illustrates depositing the dopant chemical 58 illustrated as p^{x+} by chemical or electrochemical method to deposit a controlled amount of dopant. The dopant concentration can be regulated with the charge passed during the dopant deposition step or by surface limiting phenomena, such as absorption, and it can also be controlled by changing the relative thickness of the semiconductor deposited in the first step above versus the charge passed during the dopant deposition step.

Next the same semiconductor solutions are introduced as in the first step, and this sequence is repeated until the target thickness is built.

After this, the structure is annealed as discussed herein above.

The following non-limiting examples are provided to further illustrate the present disclosure.

### EXAMPLE 1

### EC-ALD of InAs Compound Semiconductor Films

The EC-ALD cycle used to deposit InAs involved sequential depositions of In and As. The cycle used for depositing InAs is as follows: the As solution was flushed into the cell for 2 s (40 mL/min), and held quiescent for 8 s, all at the potential chosen for As deposition. Blank solution was then flushed through the cell for 3 s, followed by filling the cell with the In solution for 2 s, and holding quiescent for 15 s for deposition. The cycle was completed by flushing with blank for 3 s. This cycle ideally results in the deposition of one monolayer of the compound. The deposition potentials used for making InAs on Au substrate include the deposition of As at −0.82 V and In at −0.78V (vs Ag/AgCl reference electrode). The XPS analysis, as shown in FIG. 4, of the resulting film indicated a stoichiometric deposit. This is an indication of the high quality of the deposits. It is difficult to deposit a substantial thickness using these steady state potential conditions. However, by incorporating a slope of deposition potential (−2 mV/nm), it is possible to put down significant amount of 40 nm, measured by ellipsometry on the deposit. The thickness of a deposit is determined by how many times the cycle is performed.

### EXAMPLE 2

### Incorporation of P on Si

Incorporation of pure P on a semiconductor or metallic surface is difficult because once a monolayer of P is deposited, the surface becomes self-limiting because of its insulating property. For low dopant concentration cases, a monolayer of P after a certain thickness is likely to be sufficient. If it is required to have a substantial amount of P, more than a couple of monolayer, a carrier metal is codeposited with P, such as Nip, and other conductive P alloys or compounds.

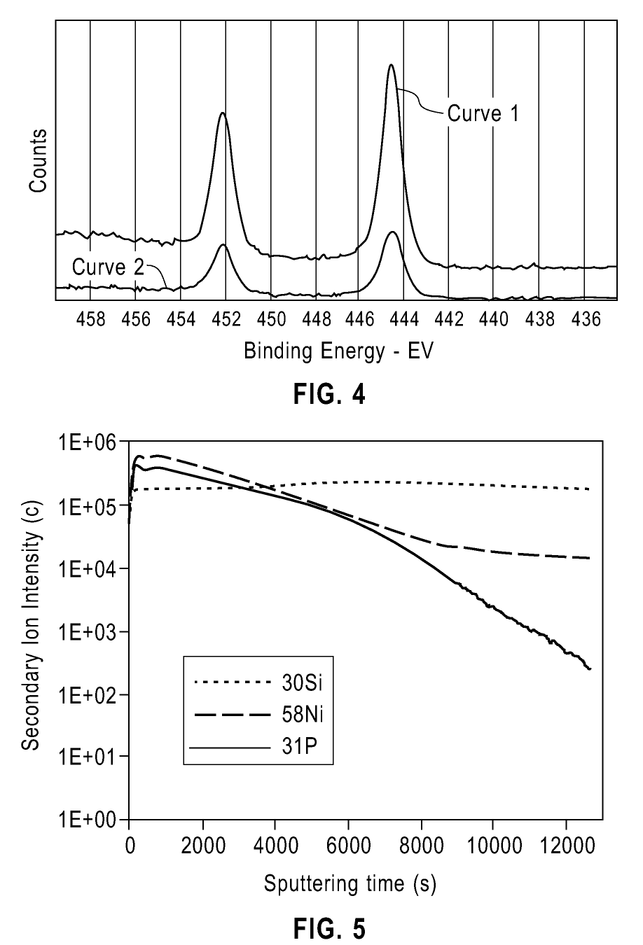

FIG. 5 shows the SIMS depth profiling of a Si sample after 60 second deposition of NiP at 10 mA/cm² current density in a NiP deposition solution. The solution is made up of 0.11M nickel sulfate, 90 mM sodium hypophosphite, 70 mM sodium acetate, and 0.1 g/l sodium lauryl sulfate. It demonstrates substantial P codeposited with Ni on the Si surface.

The term “comprising” (and its grammatical variations) as used herein is used in the inclusive sense of “having” or “including” and not in the exclusive sense of “consisting only of.” The terms “a”, “an” and “the” as used herein are understood to encompass the plural as well as the singular.

All publications, patents and patent applications cited in this specification are herein incorporated by reference, and for any and all purpose, as if each individual publication, patent or patent application were specifically and individually indicated to be incorporated by reference. In the case of inconsistencies, the present disclosure will prevail.

The foregoing description of the disclosure illustrates and describes the present disclosure. Additionally, the disclosure shows and describes only the preferred embodiments but, as mentioned above, it is to be understood that the disclosure is capable of use in various other combinations, modifications, and environments and is capable of changes or modifications within the scope of the concept as expressed herein, commensurate with the above teachings and/or the skill or knowledge of the relevant art.

The embodiments described hereinabove are further intended to explain best modes known of practicing it and to enable others skilled in the art to utilize the disclosure in such, or other, embodiments and with the various modifications required by the particular applications or uses. Accordingly, the description is not intended to limit it to the form disclosed herein. Also, it is intended that the appended claims be construed to include alternative embodiments.

What is claimed is:

1. A process for fabricating doped crystalline semiconductors:
which comprises sequentially electrodepositing by atomic layer electrodeposition at least one atomic monolayer or submonolayer of a first element of a first solution and optionally at least one atomic monolayer or submonolayer of a second element of a second solution on a substrate; and
repeating the sequential electrodepositing by atomic layer electrodeposition until at least one film of a semiconductor material is formed on the substrate to provide a semiconductor of a desired thickness;
then introducing a dopant chemical by absorption or electrodeposition after certain number of sequences of making a semiconductor film;
then repeating the deposition by atomic layer electrodeposition of a desired thickness of semiconductor film and introduction of dopant intermittently until the desired final thickness; and
annealing the deposited film to permit diffusion of the dopant atoms throughout the film to obtain uniform dopant concentration.

2. The process according to claim 1 wherein the annealing is carried out at a temperature of about 400° C. to about 1200° C.

3. The process according to claim 1 wherein the annealing is carried out at a temperature of about 700° C. to about 1000° C.

4. The process according to claim 1 wherein the concentration of the dopant is about 0.1% to about 10%.

5. The process according to claim 1 wherein the semiconductor is selected from the group consisting of Si, Ge, SiGe, Group III-V and Group II-VI compounds.

6. The process according to claim 1 wherein wherein the dopant is selected from the group consisting of P, B Al, Sb, Zn, Cd, C, Si, Ge and As.

7. A doped crystalline semiconductor obtained by the process of claim 1.

8. A process for fabricating doped crystalline semiconductors:
which comprises electrodepositing by bulk electrodeposition at least a layer of a semiconductor film of a desired thickness from a first solution on a substrate; and
then introducing a dopant chemical by absorption or electrodeposition after obtaining a semiconductor film of a desired thickness;
then repeating the deposition by electrodeposition of a desired thickness of semiconductor film and introduction of dopant intermittently until the desired final thickness; and
annealing the deposited film to permit diffusion of the dopant atoms throughout the film to obtain a uniform dopant concentration.

9. The process according to claim 8 wherein the annealing is carried out at a temperature of about 400° C. to about 1200° C.

10. The process according to claim 8 wherein the annealing is carried out at a temperature of about 700° C. to about 1000° C. by a thermal or rapid process.

11. The process according to claim 8 wherein the concentration of the dopant is about 0.1% to about 10%.

12. The process according to claim 8 wherein the semiconductor is selected from the group consisting of Si, Ge, SiGe, Group III-V and Group II-VI compounds.

13. The process according to claim 8 wherein wherein the dopant is selected from the group consisting of P, B Al, Sb, Zn, Cd, C, Si, Ge and As.

14. A doped crystalline semiconductor obtained by the process of claim 8.
